(19) United States
(12) Patent Application Publication
(10) Pub. No.: US 2026/0170591 A1
(43) Pub. Date: Jun. 18, 2026

(54) SYSTEMS AND METHODS FOR STORING, SHARING, AND INTEGRATING COMPUTER GRAPHIC PROCEDURAL CONTENT, CONTENT MODIFIERS, VISUAL EFFECTS, AND COMPLETE PIPELINES

(71) Applicant: JPMORGAN CHASE BANK, N.A., New York, NY (US)

(72) Inventors: Runqing YANG, Goleta, CA (US); Joseph W LIGMAN, Weston, CT (US); Elvir AZANLI, Union, NJ (US); Pranav DESHPANDE, Jersey City, NJ (US); Mengyu CHEN, Los Angeles, CA (US)

(21) Appl. No.: 18/983,911

(22) Filed: Dec. 17, 2024

(51) Int. Cl. G06T 1/20; G06T 15/00

(52) U.S. Cl. CPC G06T 1/20; G06T 15/005; G06T 2200/08

(57) ABSTRACT

Systems and methods for storing, sharing, and integrating computer graphic procedural content, content modifiers, visual effects, and complete pipelines are disclosed. In one embodiment, a method may include: (1) receiving, by a plugin computer program to a 3D software program, a request to upload a 3D pipeline project to a database; (2) locating, by the plugin computer program, a pipeline node tree for the 3D pipeline project; (3) recursively collecting, by the plugin computer program, node information and link information from the pipeline node tree; (4) sending, by the plugin computer program, a POST request with the collected node information and link information to a pipeline data management system; (5) creating, by the pipeline data management system, an instance of a pipeline data model for the collected node information and link information; and (6) saving, by the pipeline data management system, the instance to the database.

### BACKGROUND OF THE INVENTION

### 1. Field of the Invention

Embodiments relate to systems and methods for storing, sharing, and integrating computer graphic procedural content, content modifiers, visual effects, and complete pipelines.

### 2. Description of the Related Art

Organizing and sharing two and three-dimensional (3D) computer graphic workflows is both challenging and time-consuming. For innovative artists, designing and implementing a database system that stores assets and the procedural code used to create these assets is crucial for facilitating computer graphics production workflows.

### SUMMARY OF THE INVENTION

Systems and methods for storing, sharing, and integrating computer graphic procedural content, content modifiers, visual effects, and complete pipelines are disclosed. In one embodiment, a method may include: (1) receiving, by a plugin computer program to a 3D software program, a request to upload a 3D pipeline project to a database; (2) locating, by the plugin computer program, a pipeline node tree for the 3D pipeline project; (3) recursively collecting, by the plugin computer program, node information and link information from the pipeline node tree; (4) sending, by the plugin computer program, a POST request with the collected node information and link information to a pipeline data management system; (5) creating, by the pipeline data management system, an instance of a pipeline data model for the collected node information and link information; and (6) saving, by the pipeline data management system, the instance to the database.

In one embodiment, the plugin computer program further collects general information for the 3D pipeline project comprising a pipeline name, a pipeline author, and a name of the 3D software program.

In one embodiment, the instance of the pipeline data model may further include the general information.

In one embodiment, the instance of the pipeline data model may include an image of the 3D pipeline project, wherein the image may be uploaded to a web gallery.

In one embodiment, the database may include a cloud-based NoSQL database.

In one embodiment, the 3D pipeline project may include a rendering of a 3D object.

According to another embodiment, a method may include: (1) receiving, by a plugin computer program to a 3D software program and from a user, a request to download a target 3D pipeline project from a database; (2) locating, by the plugin computer program, an active pipeline workspace for a user; (3) submitting, by the plugin computer program, a request to retrieve the target 3D pipeline project from a pipeline data management system; (4) identifying, by the pipeline data management system, and Application Programming Interface (API) to the database; (5) connecting, by the pipeline data management system and using the API, (6) searching, by the pipeline data management system, the database for a target 3D pipeline project instance for the target 3D pipeline project; (7) parsing, by the pipeline data management system, the target 3D pipeline project instance resulting in node information and node link information; (8) receiving, by the plugin computer program, the node information and node link information; and (9) recursively building, by the plugin computer program, the target 3D pipeline project using the node information and the node link information in the active pipeline workspace.

In one embodiment, the target 3D pipeline project instance may further include general information for the target 3D pipeline project comprising a pipeline name, a pipeline author, and a name of the 3D software program.

In one embodiment, the pipeline data management system further parses general information from the target 3D pipeline project instance.

In one embodiment, the target 3D pipeline project instance may include an image of the target 3D pipeline project, wherein the image may be uploaded to a web gallery.

In one embodiment, the database may include a cloud-based NoSQL database.

In one embodiment, the target 3D pipeline project may include a rendering of a 3D object.

According to another embodiment, a method may include: (1) encoding by a computer program, an action prediction machine learning model with a plurality of historic modifiers used in a 3D software program into a plurality of tokens, resulting in a corpus of tokens, wherein each token is associated with one of the plurality of historic modifiers; (2) training, by the computer program, an action prediction machine learning model using the corpus of tokens; (3) receiving, by the computer program, current modifier used in the 3D software program; (4) encoding, by the computer program, the current modifier into a current token; (5) predicting, by the computer program and using the action prediction machine learning model, a predicted token based on the current token; (6) decoding, by the computer program the predicted token, resulting in a predicted modifier; and (7) pre-staging for execution, by the computer program, the predicted modifier in the 3D software program.

In one embodiment, each of the plurality of modifiers may be a one functional step in a 3D project pipeline.

In one embodiment, the 3D pipeline project may include a rendering of a 3D object.

In one embodiment, the action prediction machine learning model converts the plurality of tokens into an embedding layer of a neural network.

In one embodiment, the action prediction machine learning model uses a transformer or a statistical model to predict predicted token.

In one embodiment, the action prediction machine learning model generates a probability distribution across the plurality of tokens.

In one embodiment, the method may also include: executing, by the computer program, the predicted modifier in the 3D software program; and re-training, by the computer program, the action prediction machine learning model based on the execution.

### BRIEF DESCRIPTION OF THE DRAWINGS

For a more complete understanding of the present invention, the objects and advantages thereof, reference is now made to the following descriptions taken in connection with the accompanying drawings in which:

FIG. 1 illustrates a system for storing, sharing, and integrating computer graphic procedural content, content modifiers, visual effects, and complete pipelines according to an embodiment;

FIGS. 2A and 2B depict a method for uploading procedural content, content modifiers, and complete pipelines according to an embodiment;

FIGS. 3A and 3B depict a method for downloading procedural pipelines according to an embodiment;

FIG. 4 Depicts a Method for Action Prediction According to an embodiment;

FIG. 5 depicts an exemplary computing system for implementing aspects of the present disclosure.

### DETAILED DESCRIPTION OF PREFERRED EMBODIMENTS

Embodiments relate to systems and methods for storing, sharing, and integrating computer graphic procedural content, content modifiers, visual effects, and complete pipelines.

Embodiments may provide a unique record of procedural data that may be used to train or fine-tune a machine learning model. To achieve this, each computer graphics modifier or component of a modifier may be encoded into a token. A modifier is one functional step in a 3D project pipeline, for example, translate object 5 units in the x direction. This results in a large corpus of token representations. Using this corpus, embodiments may convert the token representations, for each modifier, into an embedding layer of a neural network, transforming them into high-dimensional vectors capturing the overall 3D project pipeline workflow. Next, a transformer or other statistical model may be used to predict the next probable token from a sequence of tokens. This generates a probability distribution across all potential next tokens, assigning a likelihood for what is the logical next modifier needed when to move to the next state within the series of computer graphics related modifiers.

Embodiments may provide a procedural modifier or set of modifiers that may be linked in order to create a complete pipeline. A pipeline is a set of procedural steps required to produce or modify a computer graphic artifact. A pipeline component consists of any type of procedural modifier: geometry, shader, animation, or visual effect where the produced artifact is algorithmically derived. This may include linking the application for code extraction and the necessary compatibility algorithms required for the automated upload, storage, and rebuilding of a sequence of objects and modifiers based on specially designed data model, user interaction, and role-based access control. Embodiments may facilitate a contextual search of computer graphics content modifiers and complete pipelines. Embodiments may use machine learning to automatically predict individual modifiers and workflows from text or image prompts. Embodiments may provide automatic analysis for inefficient rendering, semantic issues, loops and other error conditions. Embodiments may provide automatic analysis of units, scale, and other metrics for industrial design and 3D printing. Embodiments may provide generative assist, prediction of next node in the graphical node editor, prediction of materials, rigs, animations and additional model components from a specific pipeline (e.g., for example, prediction of materials from a geometry pipeline). Embodiments may provide support for real-time user collaboration (including real-time communication and co-editing), pipeline variants, history and ranking, and a real-time voting system for collaborative selection and design modeling.

Embodiments may provide artificial intelligence (AI) based automation for generating, correcting, or simplifying geometry modifiers and complete pipelines. Embodiments may use machine learning, training, or fine-tuning models from stored computer graphics procedural data. Embodiments may provide the necessary data source needed to train ML models to auto-create or predict the next modifier in a pipeline.

AI may be used to automatically suggest or auto complete the next graphics modifier, for example adding a rotation, translation, or scale. The AI process may also, automatically, generate a complete procedural workflow from a text prompt (e.g., asking “to create a chair” will generate a geometry-based series of modifiers needed to create a chair geometry, asking for an “oak” chair will create both the geometry and material shader pipeline to texture the chair with an oak color).

Embodiments may facilitate collaboration with others in both real-time and turn based scenarios. For example, individual editors may synchronize changes based on either course or fine-grain operational transformations, such as control operations (e.g., add, delete, etc.), saving or transferring complete pipelines to all users in either a turn-based or live scenario, etc.

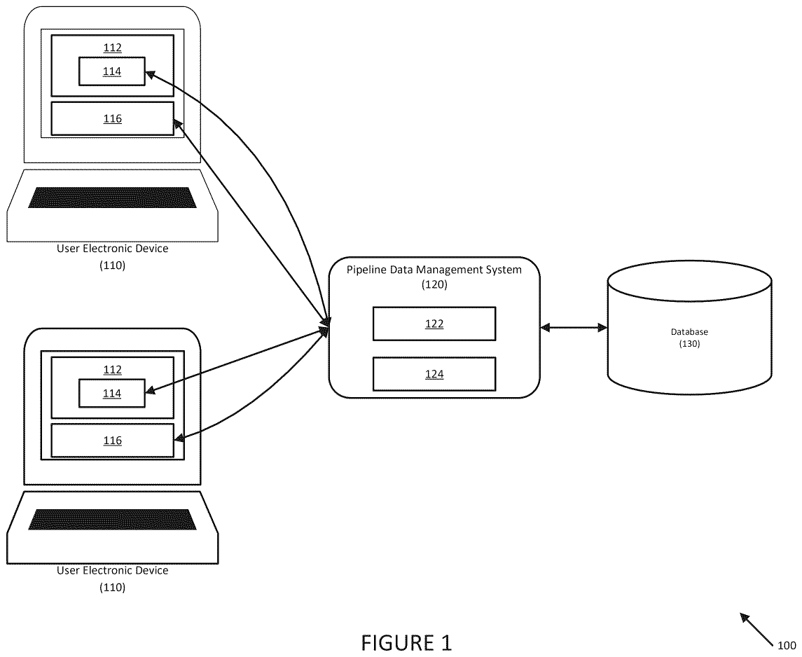

Referring to FIG. 1, a system for storing, sharing, and integrating procedural generated computer graphics content is disclosed according to an embodiment. System 100 may include one or more user electronic devices 110, each of which may execute 3D software 112 that supports 3D project pipeline building. Each electronic device 110 may be used by a user, such as an editor, a content creator, etc.

Computer graphics content creation software 112 may include plugin 114. Plugin 114 may be integrated with 3D software 112 in any suitable manner. Plugin 114 may extract the user's current workflow 3D project pipeline information and upload it to pipeline data management system (PDMS) 120 for storing in database 130. Plugin 114 may also facilitate the downloading of procedural computer graphics code stored in database 130. User authentication may be required to upload and/or download this code.

PDMS 120 may be provided on a server (e.g., a physical and/or cloud-based servers), in the cloud, etc. PDMS 120 may be responsible for user authentication, content uploads to database 130, downloads from database 130, etc., and may ensure efficient storage and security of data within database 130. PDMS 120 may also provide a range of interfaces for database administrators to maintain data integrity and security.

Database 130 may store 3D project pipeline information, for all procedural generated computer graphics data: including nodes, node links, 3D environment settings, version data, author information, and other relevant data. Database 130 may be a cloud-based database, allowing for efficient management and retrieval of large volumes of data.

User electronic devices 110 may also execute web-based user interface 116, which may provide basic login and logout functionality, and may connect to PDMS 120. Users may publish their computer graphics workflows, showcase results, view saved 3D project pipelines and modifiers along with their basic information (such as graphics type, version information, and timestamps), and perform deletion operations using web-based user interface 116.

In one embodiment, PDMS 120 may further include artificial intelligence (AI) agent 122. Alternatively, AI agent 122 may be distributed to user electronic devices in web-based interface 116, or in plugin 114. AI agent 122 may provide functionality for assisting in contextual search, through text, images, or 3D project pipeline nodes. AI agent 122 may also assist in the content creation workflow through automatic build and completion of a given set of procedural modifiers. AI agent 122 may suggest the next steps, materials, animation rigs, animations, model geometry, and other relevant constructs.

AI agent 122 may provide automatic analysis for inefficient rendering, semantic issues, loops and other error conditions. Analysis may be provided to users through analysis of relevant metrics and scaling hints based on knowledge of the entire scene.

System 100 may further include machine learning/rule-based system 124 that may provide real-time hints and analysis to the users. Machine learning/rule-based system 124 may include a linter (e.g., a software tool that analyzes source code to identify programming errors, bugs, suspicious constructs, etc.) that recognizes anti-patterns, which are commonly used patterns that may produce unintended consequences. Machine learning/rule-based system 124 may recognize these and provide hints to users on how to improve their overall workflows. For example, the linter may compare common segments of the pipeline graph against a set of predefined segments known to produce inefficient outputs, including high poly and duplicate geometries, excessively large textures and other undesirable features.

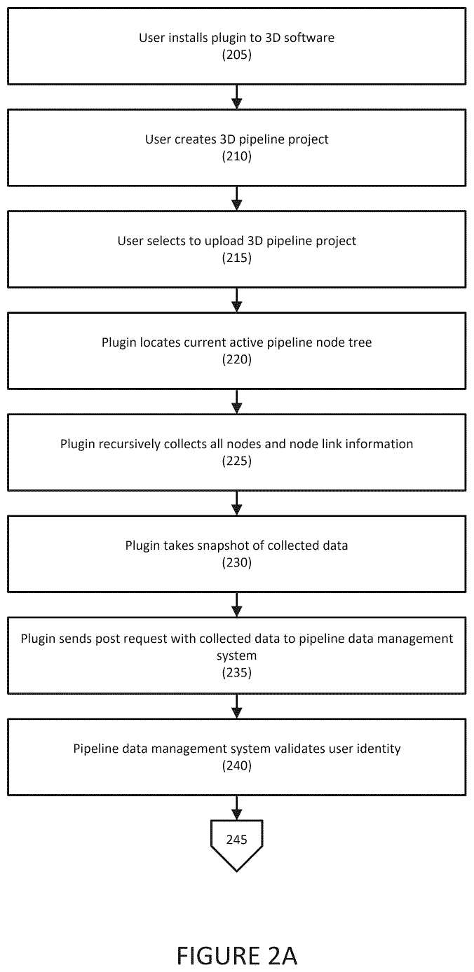

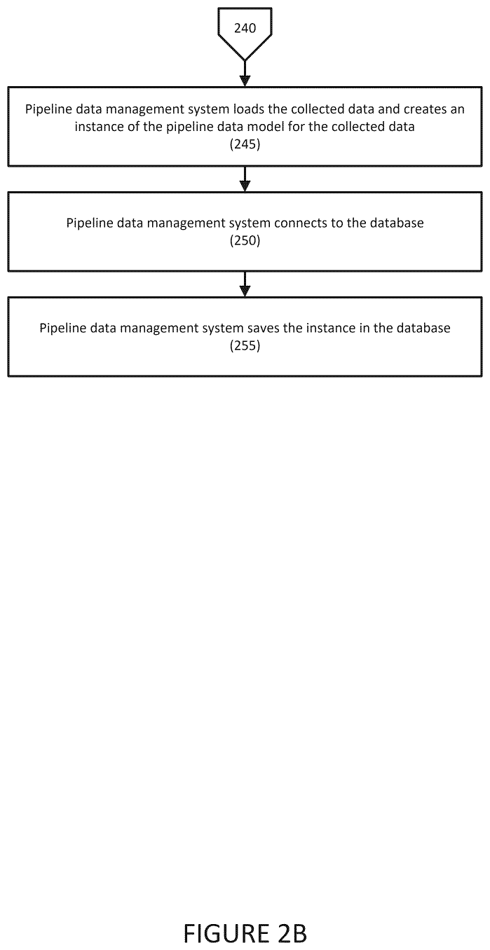

Referring to FIGS. 2A and 2B, a method for uploading 3D pipelines is disclosed according to an embodiment.

In step 205, a user may install a plugin to 3D software that supports 3D project pipeline building.

In step 210, using the 3D software, a user may create a 3D pipeline project, such as rendering of a 3D object.

In step 215, using the 3D software, the user may select to upload the 3D pipeline project to a database. Alternatively, or in addition, the plugin may periodically perform real-time synchronization with the PDMS.

In step 220, the plugin may locate the current active pipeline node tree for the 3D pipeline project, and in step 225, the plugin may recursively collect all nodes and node link information for the pipeline node tree. A 3D pipeline is a procedural representation of a computer graphics model. The model exists independently of the rendered view as presented to the end-user. Since the pipeline is a procedural representation, and not sequence of meshes or other encoded data, the model may be extended or modified, in a non-destructive way, by adding additional modifiers. The model is stored independently of the rendered scene. The structure of the pipeline is programmatic, and its rendered scene may be created by executing the sequence of modifiers, step-by-step in sequence across the graph. The pipeline sequence may be made up of a tree of modifiers that represent the scene, where each node modifier may include, for example, structural information (e.g., input socket, output socket node settings, etc.), node link information, etc.

Examples of node link information may include user-defined node parameters (e.g., the node can contain certain content for output provided by the user, such as a natural language sentence to be used as AI model prompt for texture generation; user interface (UI) rendering settings that may define how the node may display or render itself (e.g., a node may render a thumbnail of how the output may look like, it can a pre-generated image, or rendered on the fly based on input); custom code/scripts (e.g., a node may contain a piece of code provided by the user to execute on the fly such as HLSL or GLSL shader code that can be compiled and executed on the fly); code compilation settings/data (e.g., if a 3D pipeline is created for rendering or custom scripting purpose, it may also contain some compilation settings/options, such as the target specification, debugging flags, compiler/linker options, etc.); the nodes'reference at two ends, meta-data, and the necessary procedural modifier types, procedural modifier attributes, connection data needed to recreate the graph, etc.

In step 230, the plugin may take a snapshot of the collected data. A snapshot is a complete representation of the pipeline for a given state and may include some or all of the information collected in step 220.

In step 235, the plugin may send a HTTP POST request with the collected data to pipeline data management system. The plugin may further provide general information for the 3D pipeline project, including the pipeline name, author, version, visibility, time created, 3D software name, etc.).

In step 240, the pipeline data management system may validate the user's identity. Any suitable authentication mechanism may be used as is necessary and/or desired.

In step 245, the pipeline data management system may load the collected data and may create an instance of the pipeline data model for the collected data. The pipeline data model may include the general information, the node information, the node links information, and an image for a web gallery.

In step 250, the pipeline data management system may connect to a database, such as a cloud-based NoSQL database, and in step 255, may save the instance in the database. The image may be made available in a gallery for other users to view.

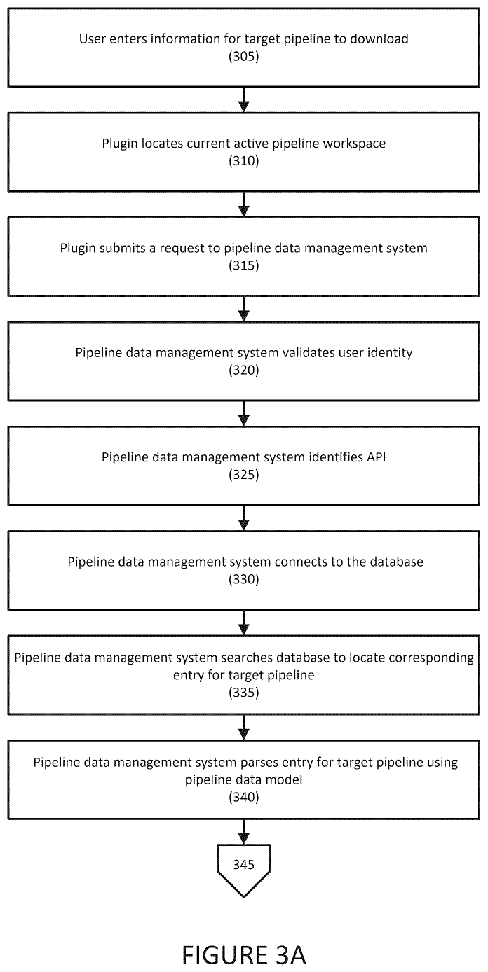

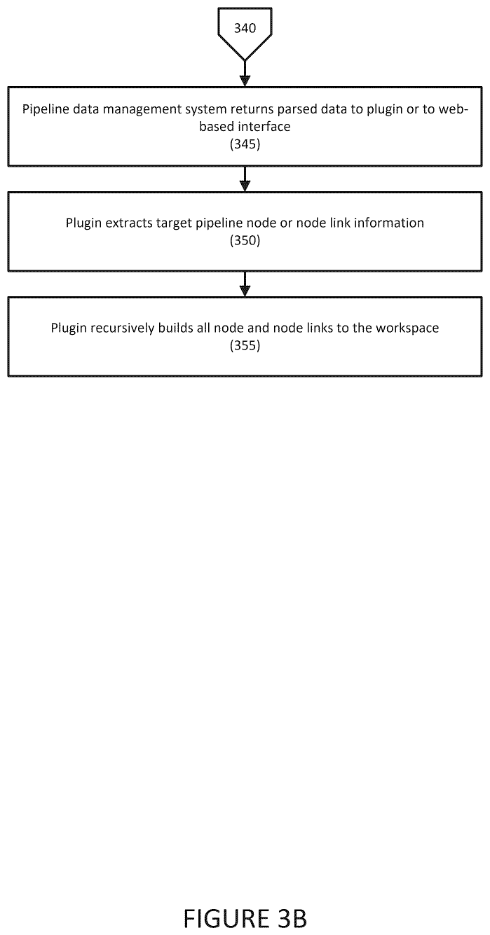

Referring to FIGS. 3A and 3B, a method for downloading a 3D pipeline instance is disclosed according to an embodiment.

In step 305, using the 3D software with the plugin, or using a web-based interface, a user may enter information for target pipeline to download. In one embodiment, the user may provide identifying information, such as a link, a project name, an author, etc. In another embodiment, the user may browse images in an image gallery using the web-based interface.

In step 310, if using the plugin, the plugin may locate the user's current active pipeline workspace. In one embodiment, the user's current active pipeline workspace may be provided with a modifier by a digital content creation tool.

In step 315, the plugin may submit a request to pipeline data management system to retrieve the target 3D project pipeline. The request may be a GET, a REST, a WebSockets, a remote procedure call (e.g., gRPC), or any other suitable protocol.

If using the web-based interface, the web-based interface may submit the request to the pipeline data management system.

In step 320, the pipeline data management system may validate the user's identity. Any suitable authentication mechanism may be used as is necessary and/or desired.

In step 325, the pipeline data management system may identify the API that provides a connection to the backend and to the database.

In step 330, the pipeline data management system may connect to the database, and in step 335, may search the database to locate the corresponding instance for the target 3D project pipeline.

In step 340, the pipeline data management system may parse the instance for the target 3D project pipeline using the pipeline data model. This may return the general information, the node information, and the node links information.

In step 345, the pipeline data management system may return the parsed data to the plugin or to the web-based interface, depending on where the request originated.

In step 350, if the user is using the plugin, the plugin may extract the target 3D project pipeline node or node link information from the parsed data, and in step 355, may recursively build all node and node links in the active pipeline workspace.

If the user is using the web-based interface, the parsed data may be stored in a user workspace.

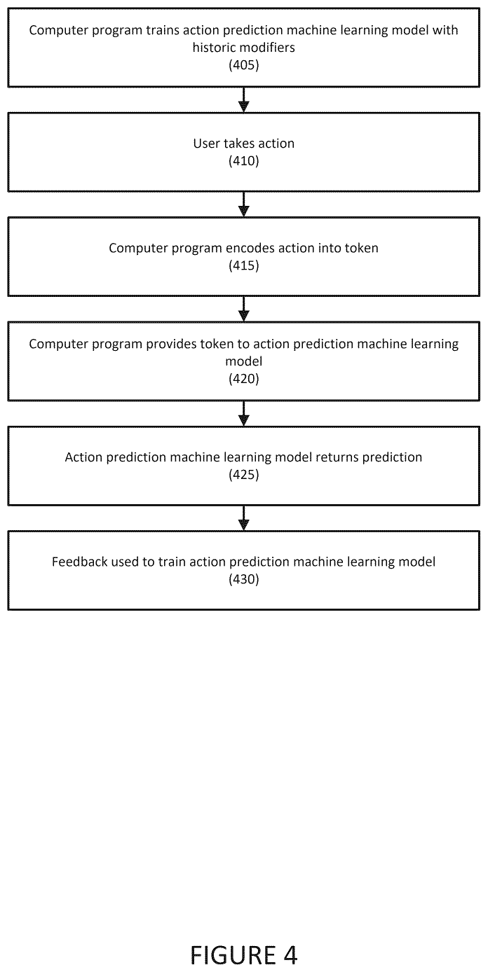

Referring to FIG. 4, a method for action prediction is disclosed according to an embodiment.

In step 405, a computer program may train an action prediction machine learning model with historic modifiers. A modifier is one functional step in a 3D project pipeline, for example, translate object 5 units in the x direction. The computer program may encode the modifier into a token using any standard tokenizer, resulting in large corpus of tokens, with each token representing a different modifier.

The computer program may use the tokens to train an action prediction machine learning model. For example, using the corpus of tokens, the action prediction machine learning model may convert the tokens into an embedding layer, transforming them into high-dimensional vectors capturing the overall pipeline workflow.

In step 410, a user may take an action, such as a modifier, with a 3D software program.

In step 415, the computer program may encode the modifier to a token.

In step 420, the computer program may provide the token to the action prediction machine learning model, and in step 425, the action prediction machine learning model may output a prediction for the next modifier. For example, the action prediction machine learning model may use a transformer or other statistical model to predict the next probable token from a sequence of tokens. This generates a probability distribution across all potential next tokens, assigning a likelihood for what is the logical next modifier needed when to move to the next state within the series of computer graphics related modifiers.

In step 425, the computer program may set the predicted modifier as a default action. The predicted modifier may be pre-staged for execution and may be cancelled if the user does not wish to execute the predicted modifier.

In step 430, the action taken by the user may be used to train the action prediction machine learning model.

In embodiments, users may collaborate, in real-time, on a project. For example, two users may work on the same computer graphics 3D project pipeline at the same time alternate locations. Edits may be applied immediately and checking for changes when saving. Merge conflicts are resolved “using last write wins” strategy. For example, users may make changes to their respective local versions, and these changes may be copied to the centralized server. The local changes may be pushed and pulled through user driven events.

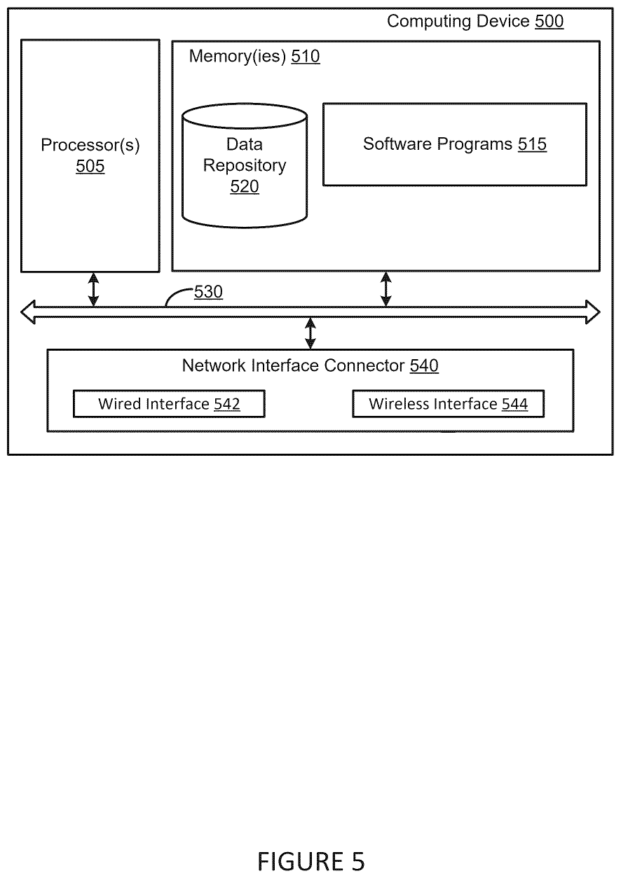

FIG. 5 depicts an exemplary computing system for implementing aspects of the present disclosure. FIG. 5 depicts exemplary computing device 500. Computing device 500 may represent the system components described herein. Computing device 500 may include processor 505 that may be coupled to memory 510. Memory 510 may include volatile memory. Processor 505 may execute computer-executable program code stored in memory 510, such as software programs 515. Software programs 515 may include one or more of the logical steps disclosed herein as a programmatic instruction, which may be executed by processor 505. Memory 510 may also include data repository 520, which may be nonvolatile memory for data persistence. Processor 505 and memory 510 may be coupled by bus 530. Bus 530 may also be coupled to one or more network interface connectors 540, such as wired network interface 542 or wireless network interface 544. Computing device 500 may also have user interface components, such as a screen for displaying graphical user interfaces and receiving input from the user, a mouse, a keyboard and/or other input/output components (not shown).

Hereinafter, general aspects of implementation of the systems and methods of embodiments will be described.

Embodiments of the system or portions of the system may be in the form of a “processing machine,” such as a general-purpose computer, for example. As used herein, the term “processing machine” is to be understood to include at least one processor that uses at least one memory. The at least one memory stores a set of instructions. The instructions may be either permanently or temporarily stored in the memory or memories of the processing machine. The processor executes the instructions that are stored in the memory or memories in order to process data. The set of instructions may include various instructions that perform a particular task or tasks, such as those tasks described above. Such a set of instructions for performing a particular task may be characterized as a program, software program, or simply software.

In one embodiment, the processing machine may be a specialized processor.

In one embodiment, the processing machine may be a cloud-based processing machine, a physical processing machine, or combinations thereof.

As noted above, the processing machine executes the instructions that are stored in the memory or memories to process data. This processing of data may be in response to commands by a user or users of the processing machine, in response to previous processing, in response to a request by another processing machine and/or any other input, for example.

As noted above, the processing machine used to implement embodiments may be a general-purpose computer. However, the processing machine described above may also utilize any of a wide variety of other technologies including a special purpose computer, a computer system including, for example, a microcomputer, mini-computer or mainframe, a programmed microprocessor, a micro-controller, a peripheral integrated circuit element, a CSIC (Customer Specific Integrated Circuit) or ASIC (Application Specific Integrated Circuit) or other integrated circuit, a logic circuit, a digital signal processor, a programmable logic device such as a FPGA (Field-Programmable Gate Array), PLD (Programmable Logic Device), PLA (Programmable Logic Array), or PAL (Programmable Array Logic), or any other device or arrangement of devices that is capable of implementing the steps of the processes disclosed herein.

The processing machine used to implement embodiments may utilize a suitable operating system.

It is appreciated that in order to practice the method of the embodiments as described above, it is not necessary that the processors and/or the memories of the processing machine be physically located in the same geographical place. That is, each of the processors and the memories used by the processing machine may be located in geographically distinct locations and connected so as to communicate in any suitable manner. Additionally, it is appreciated that each of the processor and/or the memory may be composed of different physical pieces of equipment. Accordingly, it is not necessary that the processor be one single piece of equipment in one location and that the memory be another single piece of equipment in another location. That is, it is contemplated that the processor may be two pieces of equipment in two different physical locations. The two distinct pieces of equipment may be connected in any suitable manner. Additionally, the memory may include two or more portions of memory in two or more physical locations.

To explain further, processing, as described above, is performed by various components and various memories. However, it is appreciated that the processing performed by two distinct components as described above, in accordance with a further embodiment, may be performed by a single component. Further, the processing performed by one distinct component as described above may be performed by two distinct components.

In a similar manner, the memory storage performed by two distinct memory portions as described above, in accordance with a further embodiment, may be performed by a single memory portion. Further, the memory storage performed by one distinct memory portion as described above may be performed by two memory portions.

Further, various technologies may be used to provide communication between the various processors and/or memories, as well as to allow the processors and/or the memories to communicate with any other entity; i.e., so as to obtain further instructions or to access and use remote memory stores, for example. Such technologies used to provide such communication might include a network, the Internet, Intranet, Extranet, a LAN, an Ethernet, wireless communication via cell tower or satellite, or any client server system that provides communication, for example. Such communications technologies may use any suitable protocol such as TCP/IP, UDP, or OSI, for example.

As described above, a set of instructions may be used in the processing of embodiments. The set of instructions may be in the form of a program or software. The software may be in the form of system software or application software, for example. The software might also be in the form of a collection of separate programs, a program module within a larger program, or a portion of a program module, for example. The software used might also include modular programming in the form of object-oriented programming. The software tells the processing machine what to do with the data being processed.

Further, it is appreciated that the instructions or set of instructions used in the implementation and operation of embodiments may be in a suitable form such that the processing machine may read the instructions. For example, the instructions that form a program may be in the form of a suitable programming language, which is converted to machine language or object code to allow the processor or processors to read the instructions. That is, written lines of programming code or source code, in a particular programming language, are converted to machine language using a compiler, assembler or interpreter. The machine language is binary coded machine instructions that are specific to a particular type of processing machine, i.e., to a particular type of computer, for example. The computer understands the machine language.

Any suitable programming language may be used in accordance with the various embodiments. Also, the instructions and/or data used in the practice of embodiments may utilize any compression or encryption technique or algorithm, as may be desired. An encryption module might be used to encrypt data. Further, files or other data may be decrypted using a suitable decryption module, for example.

As described above, the embodiments may illustratively be embodied in the form of a processing machine, including a computer or computer system, for example, that includes at least one memory. It is to be appreciated that the set of instructions, i.e., the software for example, that enables the computer operating system to perform the operations described above may be contained on any of a wide variety of media or medium, as desired. Further, the data that is processed by the set of instructions might also be contained on any of a wide variety of media or medium. That is, the particular medium, i.e., the memory in the processing machine, utilized to hold the set of instructions and/or the data used in embodiments may take on any of a variety of physical forms or transmissions, for example. Illustratively, the medium may be in the form of a compact disc, a DVD, an integrated circuit, a hard disk, a floppy disk, an optical disc, a magnetic tape, a RAM, a ROM, a PROM, an EPROM, a wire, a cable, a fiber, a communications channel, a satellite transmission, a memory card, a SIM card, or other remote transmission, as well as any other medium or source of data that may be read by the processors.

Further, the memory or memories used in the processing machine that implements embodiments may be in any of a wide variety of forms to allow the memory to hold instructions, data, or other information, as is desired. Thus, the memory might be in the form of a database to hold data. The database might use any desired arrangement of files such as a flat file arrangement or a relational database arrangement, for example.

In the systems and methods, a variety of “user interfaces” may be utilized to allow a user to interface with the processing machine or machines that are used to implement embodiments. As used herein, a user interface includes any hardware, software, or combination of hardware and software used by the processing machine that allows a user to interact with the processing machine. A user interface may be in the form of a dialogue screen for example. A user interface may also include any of a mouse, touch screen, keyboard, keypad, voice reader, voice recognizer, dialogue screen, menu box, list, checkbox, toggle switch, a pushbutton or any other device that allows a user to receive information regarding the operation of the processing machine as it processes a set of instructions and/or provides the processing machine with information. Accordingly, the user interface is any device that provides communication between a user and a processing machine. The information provided by the user to the processing machine through the user interface may be in the form of a command, a selection of data, or some other input, for example.

As discussed above, a user interface is utilized by the processing machine that performs a set of instructions such that the processing machine processes data for a user. The user interface is typically used by the processing machine for interacting with a user either to convey information or receive information from the user. However, it should be appreciated that in accordance with some embodiments of the system and method, it is not necessary that a human user actually interact with a user interface used by the processing machine. Rather, it is also contemplated that the user interface might interact, i.e., convey and receive information, with another processing machine, rather than a human user. Accordingly, the other processing machine might be characterized as a user. Further, it is contemplated that a user interface utilized in the system and method may interact partially with another processing machine or processing machines, while also interacting partially with a human user.

It will be readily understood by those persons skilled in the art that embodiments are susceptible to broad utility and application. Many embodiments and adaptations of the present invention other than those herein described, as well as many variations, modifications and equivalent arrangements, will be apparent from or reasonably suggested by the foregoing description thereof, without departing from the substance or scope.

Accordingly, while the embodiments of the present invention have been described here in detail in relation to its exemplary embodiments, it is to be understood that this disclosure is only illustrative and exemplary of the present invention and is made to provide an enabling disclosure of the invention. Accordingly, the foregoing disclosure is not intended to be construed or to limit the present invention or otherwise to exclude any other such embodiments, adaptations, variations, modifications or equivalent arrangements.

What is claimed is:

1. A method, comprising:
receiving, by a plugin computer program to a 3D software program, a request to upload a 3D pipeline project to a database;
locating, by the plugin computer program, a pipeline node tree for the 3D pipeline project;
recursively collecting, by the plugin computer program, node information and link information from the pipeline node tree;
sending, by the plugin computer program, a POST request with the collected node information and link information to a pipeline data management system;
creating, by the pipeline data management system, an instance of a pipeline data model for the collected node information and link information; and
saving, by the pipeline data management system, the instance to the database.

2. The method of claim 1, wherein the plugin computer program further collects general information for the 3D pipeline project comprising a pipeline name, a pipeline author, and a name of the 3D software program.

3. The method of claim 2, wherein the instance of the pipeline data model further comprises the general information.

4. The method of claim 1, wherein the instance of the pipeline data model comprises an image of the 3D pipeline project, wherein the image is uploaded to a web gallery.

5. The method of claim 1, wherein the database comprises a cloud-based NoSQL database.

6. The method of claim 1, wherein the 3D pipeline project comprises a rendering of a 3D object.

7. A method, comprising:
receiving, by a plugin computer program to a 3D software program and from a user, a request to download a target 3D pipeline project from a database;
locating, by the plugin computer program, an active pipeline workspace for a user;
submitting, by the plugin computer program, a request to retrieve the target 3D pipeline project from a pipeline data management system;
identifying, by the pipeline data management system, and Application Programming Interface (API) to the database;
connecting, by the pipeline data management system and using the API,
searching, by the pipeline data management system, the database for a target 3D pipeline project instance for the target 3D pipeline project;
parsing, by the pipeline data management system, the target 3D pipeline project instance resulting in node information and node link information;
receiving, by the plugin computer program, the node information and node link information; and
recursively building, by the plugin computer program, the target 3D pipeline project using the node information and the node link information in the active pipeline workspace.

8. The method of claim 7, wherein the target 3D pipeline project instance further comprises general information for the target 3D pipeline project comprising a pipeline name, a pipeline author, and a name of the 3D software program.

9. The method of claim 8, wherein the pipeline data management system further parses general information from the target 3D pipeline project instance.

10. The method of claim 7, wherein the target 3D pipeline project instance comprises an image of the target 3D pipeline project, wherein the image is uploaded to a web gallery.

11. The method of claim 7, wherein the database comprises a cloud-based NoSQL database.

12. The method of claim 7, wherein the target 3D pipeline project comprises a rendering of a 3D object.

13. A method, comprising:
encoding by a computer program, an action prediction machine learning model with a plurality of historic modifiers used in a 3D software program into a plurality of tokens, resulting in a corpus of tokens, wherein each token is associated with one of the plurality of historic modifiers;
training, by the computer program, an action prediction machine learning model using the corpus of tokens;
receiving, by the computer program, current modifier used in the 3D software program;
encoding, by the computer program, the current modifier into a current token;
predicting, by the computer program and using the action prediction machine learning model, a predicted token based on the current token;
decoding, by the computer program the predicted token, resulting in a predicted modifier; and
pre-staging for execution, by the computer program, the predicted modifier in the 3D software program.

14. The method of claim 13, wherein each of the plurality of modifiers is a one functional step in a 3D project pipeline.

15. The method of claim 14, wherein the 3D pipeline project comprises a rendering of a 3D object.

16. The method of claim 13, wherein the action prediction machine learning model converts the plurality of tokens into an embedding layer of a neural network.

17. The method of claim 13, wherein the action prediction machine learning model uses a transformer or a statistical model to predict predicted token.

18. The method of claim 17, wherein the action prediction machine learning model generates a probability distribution across the plurality of tokens.

19. The method of claim 13, further comprising:
executing, by the computer program, the predicted modifier in the 3D software program; and
re-training, by the computer program, the action prediction machine learning model based on the execution.
